(19) United States
(12) Patent Application Publication
(10) Pub. No.: US 2013/0240253 A1
(43) Pub. Date: Sep. 19, 2013

(54) PRINTED CIRCUIT BOARD WITH GROUNDING PROTECTION

(71) Applicant: XING-HUA TANG, Shenzhen City (CN)

(72) Inventor: XING-HUA TANG, Shenzhen City (CN)

(73) Assignees: HON HAI PRECISION INDUSTRY CO., LTD., Tu-Cheng (TW); HONG FU JIN PRECISION INDUSRY (SHENZHEN) CO., LTD., Shenzhen City (CN)

(21) Appl. No.: 13/454,009

(22) Filed: Apr. 23, 2012

(30) Foreign Application Priority Data
Mar. 15, 2012 (CN) 201210068003.X

(51) Int. Cl. H05K 1/09

(52) U.S. Cl. 174/257

(57) ABSTRACT

The present disclosure provides a printed circuit board (PCB) with grounding protection. The PCB includes a grounding element. A predetermined number of via through holes or a predetermined number of soldering tin joints are distributed around the grounding element to generate a good grounding protection for the PCB.

### BACKGROUND

1. Technical Field

The disclosure relates to a printed circuit board (PCB) and, more particularly, to a PCB with grounding protection.

2. Description of Related Art

A PCB has grounding protection via a screw hole or a metal plate. As shown in FIG. 1, the PCB 10 has grounding protection via a screw hole 30. A copper area 20 is positioned around the screw hole 30. However, a circuit of the PCB 10 around the screw hole 30 is easily broken among the multilayer circuit boards and may have bad grounding protection.

Therefore, what is needed is a PCB with grounding protection to overcome the described shortcoming.

### BRIEF DESCRIPTION OF THE DRAWINGS

FIG. 1 is a schematic view of a PCB with grounding protection according to prior art.

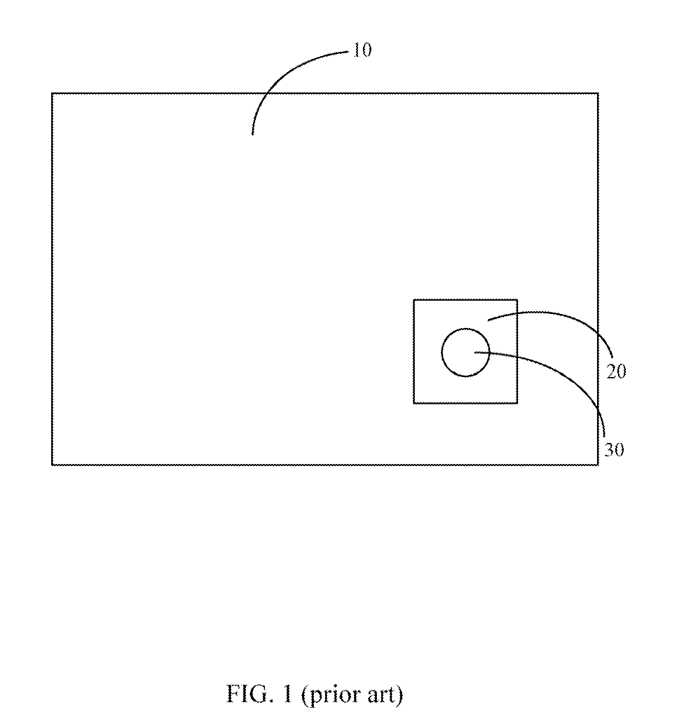

FIG. 2 is a schematic view of a PCB with grounding protection in accordance with an exemplary embodiment.

FIG. 3 is a cross sectional view of the PCB of FIG. 2.

### DETAILED DESCRIPTION

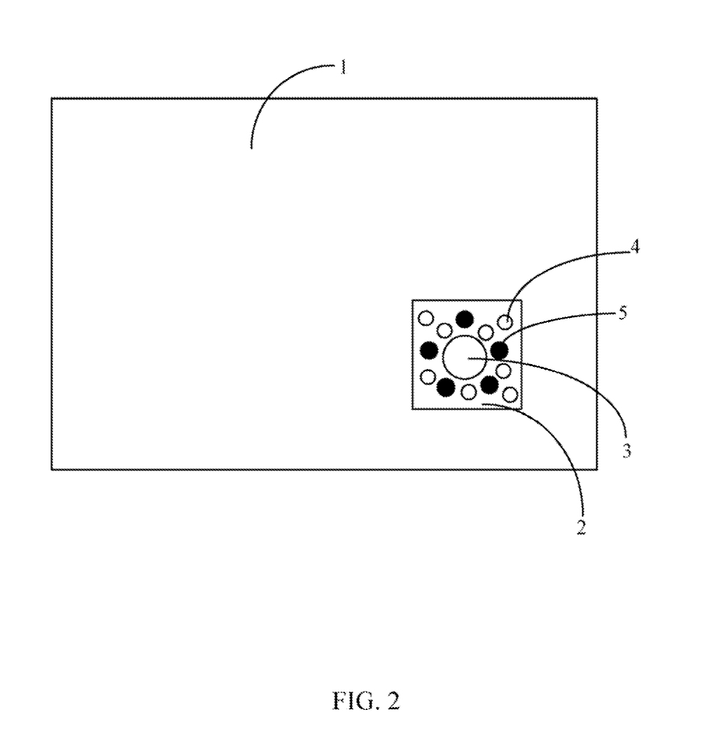

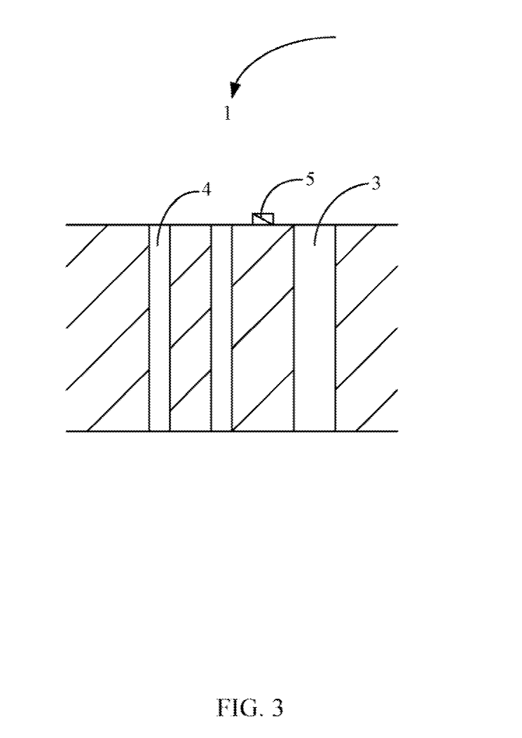

FIGS. 2 and 3, are a printed circuit board (PCB) with grounding protection (hereinafter “PCB”) 1 is composed of overlapped multilayer circuit boards. The PCB 1 includes a grounding element 3. The grounding element 3 may be a screw hole, or a metal plate, for example. For illustration purposes, a screw hole is used as an example of the grounding element 3.

At least one screw hole 3 is distributed on the PCB 1. A copper area 2 is positioned around each screw hole 3. A predetermined number of via through holes 4 are distributed in the copper area 2 around each screw hole 3 and extend through the PCB 1. The predetermined number of via through holes 4 are evenly distributed around each screw hole 3. Alternatively, a predetermined number of soldering tin joints 5 are distributed on the top layer of the PCB 1 in the copper area 2 around each screw hole 3. The predetermined number of soldering tin joints 5 are evenly distributed around each screw hole 3. In the embodiment, each soldering tin joint 5 is circular.

The multilayer circuit boards are connected together by the predetermined number of via through holes 4. Therefore, when there are disturbance sources entering the PCB 1, the predetermined number of via through holes 4 effectively and quickly vent out noise and, and generates a good grounding protection for the PCB 1.

The hardness of the copper and the screw is high, when the screw is tuned in the screw hole 3, if the screw is tilted a little, the multilayer circuit boards may not be well connected together, which results in a broken circuit among the multilayer circuit boards. Therefore, in the present disclosure, the predetermined number of soldering tin joints 5 are evenly distributed around each screw hole 3, the copper area 2 can be evenly connected with a screw, the multilayer circuit boards are well connected together, thereby avoiding a broken circuit among the multilayer circuit boards and generating a good grounding protection for the PCB 1.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A printed circuit board (PCB) comprising:
overlapped multilayer circuit boards; and
a grounding element;
wherein a predetermined number of via through holes or a predetermined number of soldering tin joints are distributed in a copper area around the grounding element.

2. The PCB as recited in claim 1, wherein the grounding element is a screw hole.

3. The PCB as recited in claim 1, wherein the grounding element is a metal plate.

4. The PCB as recited in claim 1, wherein each through hole extends through the PCB.

5. The PCB as recited in claim 1, wherein each soldering tin joint is circular and on a top layer of the overlapped multilayer circuit boards.

6. The PCB as recited in claim 1, wherein the predetermined number of via through holes are evenly distributed around the grounding element.

7. The PCB as recited in claim 1, wherein the predetermined number of soldering tin joints are evenly distributed around the grounding element.
